(19) United States
(12) Patent Application Publication
(10) Pub. No.: US 2024/0273276 A1
(43) Pub. Date: Aug. 15, 2024

(54) LAYOUT GENERATION DEVICE, LAYOUT GENERATION METHOD, AND STORAGE MEDIUM

(71) Applicant: Kioxia Corporation, Tokyo (JP)

(72) Inventor: Taiki KIMURA, Tokyo (JP)

(73) Assignee: Kioxia Corporation, Tokyo (JP)

(21) Appl. No.: 18/436,435

(22) Filed: Feb. 8, 2024

(30) Foreign Application Priority Data
Feb. 9, 2023 (JP) 2023-018679

(51) Int. Cl. G06F 30/392; G06F 30/398

(52) U.S. Cl. CPC G06F 30/392; G06F 30/398

(57) ABSTRACT

According to one embodiment, a layout generation device includes: an extraction unit extracting a plurality of origins from design data for a photomask; an obtainment unit obtaining a region corresponding to each of the origins; a grouping unit classifying the origins into one or more groups; and a layering unit transforming a distribution of origins corresponding to each of the one or more groups into layers. One or more sets of origins that form an equivalent pattern within regions corresponding to the origins are classified into an identical group. The layering unit is configured to repeat: extracting a periodicity from a first distribution corresponding to a first layer being the highest layer of the distribution; aggregating the first distribution into a second distribution based on the periodicity; and placing a second layer of the second distribution as a higher layer than the first layer of the first distribution.

### CROSS-REFERENCE TO RELATED APPLICATIONS

This application is based upon and claims the benefit of priority from Japanese Patent Application No. 2023-018679, filed Feb. 9, 2023, the entire contents of which are incorporated herein by reference.

### FIELD

Embodiments described herein relate generally to a layout generation device, and a layout generation method, and a storage medium.

### BACKGROUND

Layout generation devices that generate layout data on a photomask are known. Photomasks are used for producing memory devices such as NAND flash memories. Times taken for creating layout data and data sizes of the layout data have been increased with an increase in degrees of integration of memory devices.

### BRIEF DESCRIPTION OF THE DRAWINGS

FIG. 1 is a block diagram illustrating an example of a hardware configuration of a photomask production system according to an embodiment.

FIG. 2 is a block diagram illustrating an example of a hardware configuration of a layout generation device according to the embodiment.

FIG. 3 is a block diagram illustrating an example of a functional configuration of the layout generation device according to the embodiment.

FIG. 4 is a block diagram illustrating an example of a functional configuration of a design module according to the embodiment.

FIG. 5 is a diagram illustrating an example of a configuration of flat data according to the embodiment.

FIG. 6 is a diagram illustrating a first example of a unit pattern and a two-dimensional distribution of origins that belong to a group corresponding to the unit pattern according to the embodiment.

FIG. 7 is a diagram illustrating a second example of a unit pattern and a two-dimensional distribution of origins that belong to a group corresponding to the unit pattern according to the embodiment.

FIG. 8 is a diagram illustrating a third example of a unit pattern and a two-dimensional distribution of origins that belong to a group corresponding to the unit pattern according to the embodiment.

FIG. 9 is a diagram illustrating an example of periodicities possessed by a two-dimensional distribution of clipping origins in a first layer according to the embodiment.

FIG. 10 is a diagram illustrating an example of periodicities possessed by a two-dimensional distribution of repetition origins in a second layer according to the embodiment.

FIG. 11 is a diagram illustrating an example of periodicities possessed by a two-dimensional distribution of repetition origins in a third layer according to the embodiment.

FIG. 12 is a diagram illustrating an example of periodicities possessed by a two-dimensional distribution of repetition origins in a fourth layer according to the embodiment.

FIG. 13 is a diagram illustrating an example of periodicities possessed by a two-dimensional distribution of repetition origins in a fifth layer according to the embodiment.

FIG. 14 is a flowchart illustrating an example of a layout data generation process in the layout generation device according to the embodiment.

FIG. 15 is a flowchart illustrating an example of a design data generation process in the design module according to the embodiment.

FIG. 16 is a flowchart illustrating an example of a layered data creation process in a layered data creation unit according to the embodiment.

FIG. 17 is a flowchart illustrating an example of a correction and inspection process in a correction module and an inspection module according to the embodiment.

FIG. 18 is a block diagram illustrating an example of a functional configuration of a design module according to a modification.

FIG. 19 is a flowchart illustrating an example of a design data generation process in the design module according to the modification.

### DETAILED DESCRIPTION

In general, according to one embodiment, a layout generation device includes: an extraction unit extracting a plurality of origins from design data for a photomask; an obtainment unit obtaining a region corresponding to each of the origins; a grouping unit classifying the origins into one or more groups; and a layering unit transforming a distribution of origins corresponding to each of the one or more groups into layers. One or more sets of origins that form an equivalent pattern within regions corresponding to the origins are classified into an identical group. The layering unit is configured to repeat: extracting a periodicity from a first distribution corresponding to a first layer being the highest layer of the distribution; aggregating the first distribution into a second distribution based on the periodicity; and placing a second layer of the second distribution as a higher layer than the first layer of the first distribution.

Embodiments will be described below with reference to the drawings. In the following description, constituent components having the same function and configuration will be given common reference character.

### 1. Embodiment

### 1.1 Configuration

### 1.1.1 Photomask Production System

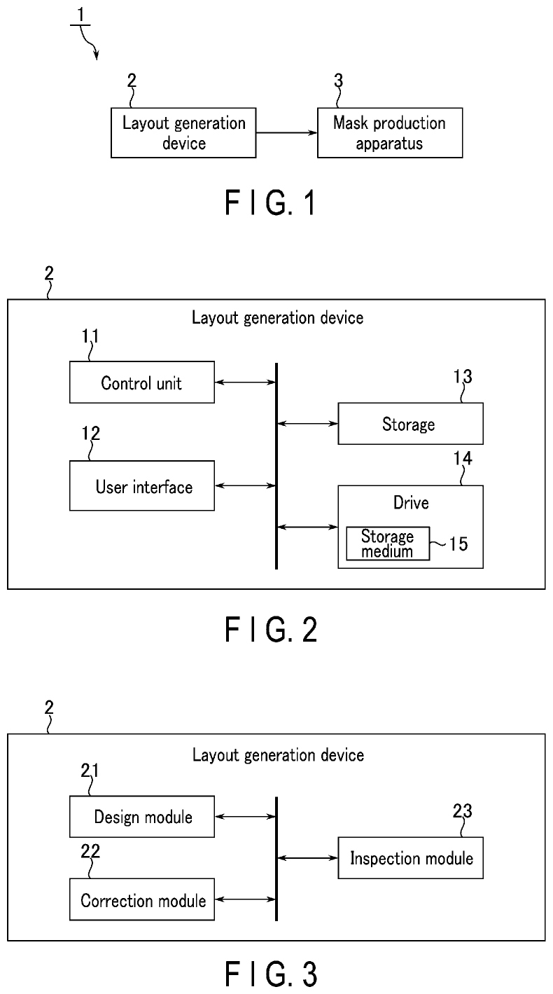

FIG. 1 is a block diagram illustrating an example of a hardware configuration of a photomask production system according to an embodiment. A photomask production system 1 is a system for producing a photomask. The photomask production system 1 includes a layout generation device 2, and a mask production apparatus 3.

The layout generation device 2 is a computer configured to execute a mask data preparation (MDP) process. The layout generation device 2 generates layout data. The layout data is data that represents a layout of a pattern to be formed on a photomask.

The mask production apparatus 3 is an electron-beam lithography apparatus. The mask production apparatus 3 draws a pattern based on the layout data generated by the layout generation device 2 by irradiating a substrate being a material of the photomask with an electron beam. The substrate with the pattern drawn thereon is processed into the photomask by a development process and an etching process.

The photomask is used for, for example, producing a memory device. The memory device is, for example, a NAND flash memory including a memory cell array of a three-dimensional structure. The memory cell array has a plurality of memory pillar structures. Each of the memory pillar structures includes a plurality of memory cells that are three-dimensionally stacked.

### 1.1.2 Layout Generation Device

FIG. 2 is a block diagram illustrating an example of a hardware configuration of a layout generation device according to the embodiment. The layout generation device 2 includes a control unit 11, a user interface 12, a storage 13, a drive 14, and storage medium 15.

The control unit 11 is a circuit that controls components of the layout generation device 2 as a whole. The control unit 11 includes a central processing unit (CPU), a random access memory (RAN), a read only memory (ROM), and the like. The ROM of the control unit 11 stores a program and the like to be used in various processes in the layout generation device 2. The CPU of the control unit 11 controls the entire layout generation device 2 according to the program stored in the ROM of the control unit 11. The RAM of the control unit 11 is used as a working area for the CPU of the control unit 11.

The user interface 12 is an interface that handles communication between a user and the control unit 11. The user interface 12 includes a piece of input equipment and a piece of output equipment. The input equipment includes, for example, a touch panel, an operation button, and the like. The output equipment includes, for example, a liquid crystal display (LCD) or an electroluminescence (EL) display. The user interface 12 converts an input from the user into an electric signal and then sends the electric signal to the control unit 11. The user interface 12 outputs, to the user, results of the various processes executed based on the input from the user.

The storage 13 includes, for example, a hard disk drive (HDD) or a solid state drive (SSD). The storage 13 stores data to be used in the various processes in the layout generation device 2.

The drive 14 is a piece of equipment for reading software stored in the storage medium 15. The drive 14 includes, for example, a compact disk drive, a digital versatile disk (DVD) drive, and the like.

The storage medium 15 is a medium that stores the software through an electrical, magnetic, optical, mechanical, or chemical action. The storage medium 15 may store a program for executing the various processes in the layout generation device 2.

FIG. 3 is a block diagram illustrating an example of a functional configuration of the layout generation device according to the embodiment. The CPU of the control unit 11 loads the program stored in the ROM of the control unit 11 or in the storage medium 15 onto the RAM of the control unit 11. The CPU of the control unit 11 then interprets and executes the program loaded onto the RAM of the control unit 11. In this way, the layout generation device 2 functions as a computer including a design module 21, a correction module 22, and an inspection module 23.

The design module 21 is a functional block for generating design data. The design data is data that represents a layout of a perfect pattern expected to be transferred to a substrate with a photomask. The design module 21 sends the generated design data to the correction module 22.

The correction module 22 is a functional block for correcting the design data. Specifically, the correction module 22 executes an optical proximity correction (OPC) process and a sub resolution assist feature (SRAF) generation process on the design data generated by the design module 21 or design data revised by the inspection module 23. The OPC process may include correction based on inverse lithography technology (ILT). In addition, the OPC process and the SRAF generation process may each be a rule-based process or a model-based process. The correction module 22 sends the corrected design data to the inspection module 23.

The inspection module 23 is a functional block for inspecting the design data corrected by the correction module 22. Specifically, the inspection module 23 executes a lithography simulation on the corrected design data. With the lithography simulation, the inspection module 23 determines whether a desired pattern can be obtained by a lithography process with a photomask based on the corrected design data. In a case where the inspection module 23 determines that the desired pattern cannot be obtained (not good), the inspection module 23 subjects the design data to a revision process and sends the revised design data to the correction module 22. In a case where the inspection module 23 determines that the desired pattern can be obtained (good), the inspection module 23 tapes out the corrected design data as layout data to the mask production apparatus 3.

### 1.1.3 Design Module

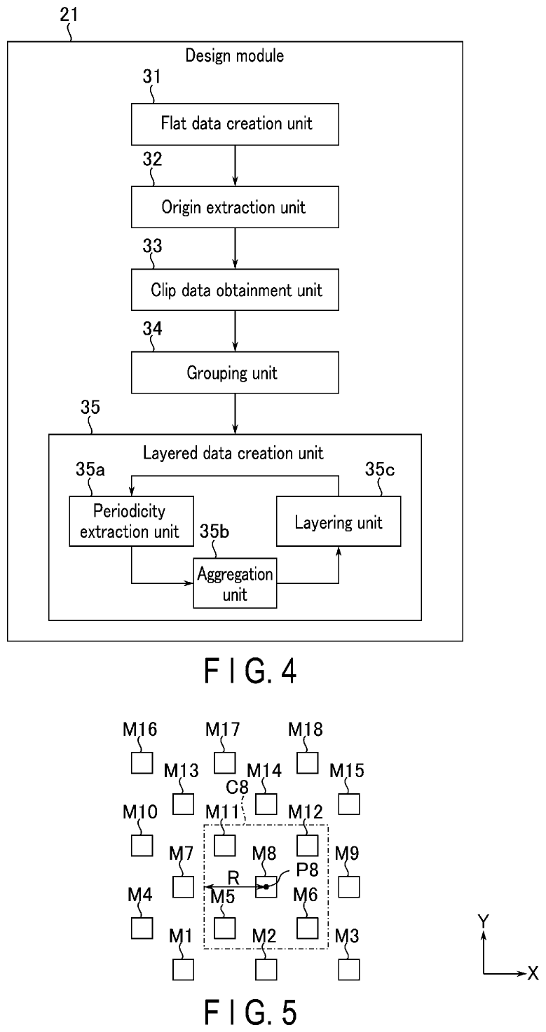

FIG. 4 is a block diagram illustrating an example of a functional configuration of the design module according to the embodiment. The design module 21 includes a flat data creation unit 31, an origin extraction unit 32, a clip data obtainment unit 33, a grouping unit 34, and a layered data creation unit 35.

The flat data creation unit 31 generates flat design data (flat data). The flat data creation unit 31 sends the generated flat data to the origin extraction unit 32. The flat data is non-compressed design data that is generated by computer-aided design (CAD) or the like. The flat data has no layered data structure. The flat data therefore has a significantly large data size. Specifically, for example, flat data on a layout of the memory pillar structure of the NAND flash memory can have a data size on an order of gigabyte (GB).

The origin extraction unit 32 extracts a plurality of clipping origins from the flat data. The origin extraction unit 32 sends coordinate information on each of the extracted clipping origins to the clip data obtainment unit 33. The clipping origins each corresponds to a central processing point in the OPC process by the correction module 22 and in the lithography simulation by the inspection module 23. Specifically, for example, in a case of a line-based mask pattern, the origin extraction unit 32 extracts, as a clipping origin, a center of an edge used for subjecting the mask pattern to jog partitioning. Alternatively, for example, in a case of a hole-based mask pattern, the origin extraction unit 32 extracts a center of the mask pattern as a clipping origin. That is, in a case where a shape of a mask pattern is hole-based, the origin extraction unit 32 extracts clipping origins that correspond in number to mask patterns.

Based on the coordinate information on the each of the clipping origins, the clip data obtainment unit 33 obtains clip data from the flat data. That is, the clip data obtainment unit 33 obtains clip data items that correspond in number to the clipping origins. The clip data obtainment unit 33 sends to the obtained clip data items to the grouping unit 34. Each of the clip data items is a data item, in the flat data, on a mask pattern corresponding to a region that has a center indicated by coordinate information on a clipping origin and has edges located at a distance equal to or greater than an optical radius from the center. That is, the clip data is an example of a pattern.

FIG. 5 is a diagram illustrating an example of a configuration of the flat data and the clip data according to the embodiment. FIG. 5 illustrates eighteen hole mask patterns M1 to M18, which are disposed on an XY plane, with solid lines as a specific example of the flat data. FIG. 5 also illustrates a clip data item C8 that corresponds to a clipping origin P8 of the mask pattern M8, with dash-dot lines. Note that the XY plane is a plane formed by an X direction and a Y direction that intersect with each other.

The origin extraction unit 32 extracts, as the clipping origin P8 corresponding to the mask pattern M8, coordinates of the center of the mask pattern M8. The clip data obtainment unit 33 obtains, as the clip data item C8, a rectangular region that is centered at the clipping origin P8 and has sides twice an optical radius R. In the example illustrated in FIG. 5, the clip data item C8 includes five mask patterns M5, M6, M8, M11, and M12.

Referring to FIG. 4 again, a functional configuration of the design module 21 will be described.

The grouping unit 34 classifies the clip data items into one or more groups. A plurality of clip data items classified into an identical group are regarded as being identical. Here, “clip data items regarded as being identical” are clip data items that are completely identical, clip data items that are in line symmetry, or clip data items that are in rotational symmetry. Hereinafter, “being regarded as being identical” will be also referred to as “being equivalent.”

As a result of the classification by the grouping unit 34, each group is associated with one unique clip data item (distinguishable from a clip data item associated with another group or other groups) and with a plurality of clipping origins from which the unique clip data item is obtained. Hereinafter, the unique clip data item associated with each group will be also referred to as a “unit pattern.” For each group, the grouping unit 34 sends a unit pattern belonging to the group and a set of the clipping origins to the layered data creation unit 35.

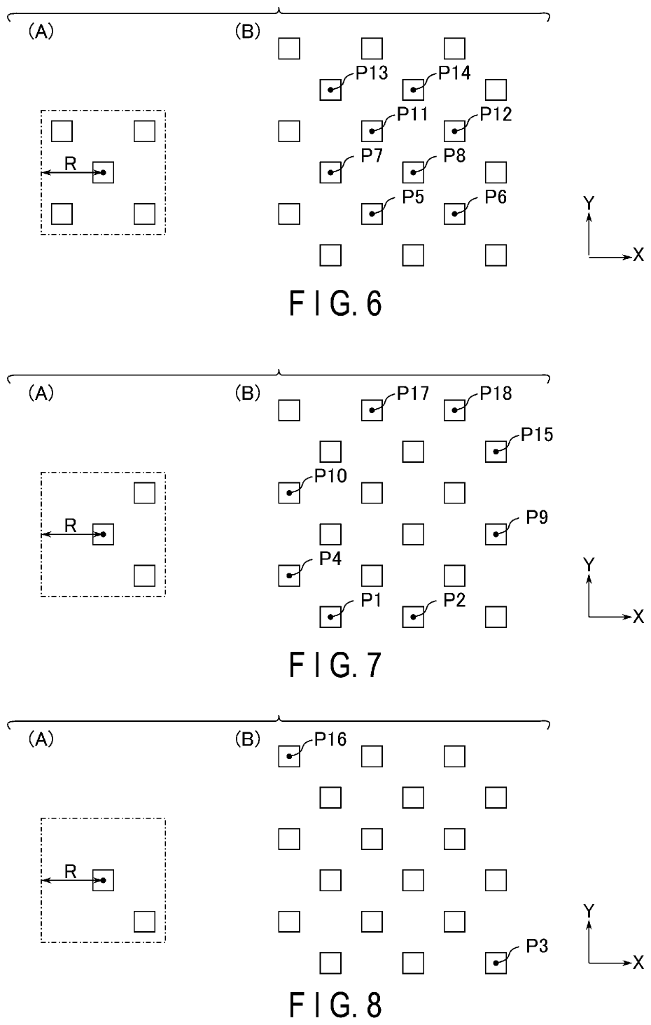

FIG. 6 is a diagram illustrating a first example of a unit pattern and a two-dimensional distribution of clipping origins that belong to a group corresponding to the unit pattern according to the embodiment. FIG. 7 is a diagram illustrating a second example of a unit pattern and a two-dimensional distribution of clipping origins that belong to a group corresponding to the unit pattern according to the embodiment. FIG. 8 is a diagram illustrating a third example of a unit pattern and a two-dimensional distribution of clipping origins that belong to a group corresponding to the unit pattern according to the embodiment. A part (A) of FIG. 6, a part (A) of FIG. 7, and a part (A) of FIG. 8 illustrate three types of unit patterns that are obtained by grouping clip data items extracted from the flat data illustrated in FIG. 5. A part (B) of FIG. 6, a part (B) of FIG. 7, and a part (B) of FIG. 8 illustrate two-dimensional distributions of clipping origins that belong to groups corresponding to the unit pattern illustrated in the part (A) of FIG. 6, the unit pattern illustrated in the part (A) of FIG. 7, and the unit pattern illustrated in the part (A) of FIG. 8, respectively.

The unit pattern of the first example illustrated in FIG. 6 includes five mask patterns within the unit pattern. Out of the eighteen clip data items obtained from the flat data, eight clip data items obtained from eight clipping origins P5, P6, P7, P8, P11, P12, P13, and P14 are equivalent to the unit pattern of the first example. The grouping unit 34 thus classifies the unit pattern of the first example and a set of the eight clipping origins P5, P6, P7, P8, P11, P12, P13, and P14 into one group.

The unit pattern of the second example illustrated in FIG. 7 includes three mask patterns within the unit pattern. Out of the eighteen clip data items obtained from the flat data, eight clip data items obtained from eight clipping origins P1, P2, P4, P9, P10, P15, P17, and P18 are equivalent to the unit pattern of the second example. The grouping unit 34 thus classifies the unit pattern of the second example and a set of the eight clipping origins P1, P2, P4, P9, P10, P15, P17, and P18 into one group.

The unit pattern of the third example illustrated in FIG. 8 includes two mask patterns within the unit pattern. Out of the eighteen clip data items obtained from the flat data, two clip data items obtained from two clipping origins P3 and P16 are equivalent to the unit pattern of the third example. The grouping unit 34 thus classifies the unit pattern of the third example and a set of the two clipping origins P3 and P16 into one group.

Referring to FIG. 4 again, a functional configuration of the design module 21 will be described.

The layered data creation unit 35 generates layered design data (layered data). The layered data creation unit 35 sends the generated layered data as the design data to the correction module 22. The layered data is design data being the flat data compressed and has a layered data structure. Therefore, the layered data is smaller in data size than the flat data. Specifically, for example, layered data on a layout of the memory pillar structure of the NAND flash memory can have a data size on an order of megabyte (MB).

The layered data creation unit 35 includes a periodicity extraction unit 35a, an aggregation unit 35b, and layering unit 35c.

The periodicity extraction unit 35a extracts, for each group, periodicities from a two-dimensional distribution of a plurality of origins that belong to the group. The periodicity extraction unit 35a sends information that represents the extracted periodicities to the aggregation unit 35b. The periodicity means a property of the two-dimensional coordinates of the origins being distributed at equal intervals in a certain direction. For example, in a case where m origins are distributed in the X direction at intervals Dx, the m origins possess a periodicity (Dx, m) in the X direction. For example, in a case where n origins are distributed in the Y direction at intervals Dy, the n origins possess a periodicity (Dy, n) in the Y direction.

Based on the periodicities extracted by the periodicity extraction unit 35a, the aggregation unit 35b aggregates, for each group, the two-dimensional distribution of the origins that belong to the group into a two-dimensional distribution of a smaller number of origins. The aggregation unit 35b sends a combination of the distribution after the aggregation and the distribution before the aggregation to the layering unit 35c.

The layering unit 35c transforms the two-dimensional distribution of the origins into layers by taking the two-dimensional distribution of the origins before the aggregation as a lower layer, taking the two-dimensional distribution of the origins after the aggregation as a higher layer, and associating the lower layer and the higher layer with each other. The layering unit 35c sends the two-dimensional distribution of the origins as the higher layer obtained by the layering to the periodicity extraction unit 35a.

A combination of the extraction of periodicities by the periodicity extraction unit 35a, the aggregation of the two-dimensional distribution of the origins by the aggregation unit 35b, and the layering by the layering unit 35c is repeated. The repetition makes the two-dimensional distribution of a plurality of origins belonging to each group multi-layered.

That is, in a case where a layering process is performed for a first time based on a two-dimensional distribution of a plurality of clipping origins, the periodicity extraction unit 35a extracts, for each group, periodicities from a two-dimensional distribution of a plurality of clipping origins that belong to the group. Based on the periodicities extracted by the periodicity extraction unit 35a, the aggregation unit 35b aggregates, for each group, the two-dimensional distribution of the clipping origins that belong to the group into a two-dimensional distribution of a smaller number of repetition origins. The layering unit 35c transforms the two-dimensional distribution of the origins into layers by taking the two-dimensional distribution of the clipping origins before the aggregation as a lower layer, taking the two-dimensional distribution of the repetition origins after the aggregation as a higher layer, and associating the lower layer and the higher layer with each other. Here, the two-dimensional distribution of the repetition origins corresponding to the higher layer is defined independently of the two-dimensional distribution of the clipping origins corresponding to the lower layer.

In addition, in a case where the layering process is performed for second and subsequent times based on the two-dimensional distribution of the repetition origins, the periodicity extraction unit 35a extracts, for each group, periodicities from a two-dimensional distribution of a plurality of repetition origins that belong to the group. Based on the periodicities extracted by the periodicity extraction unit 35a, the aggregation unit 35b aggregates, for each group, the two-dimensional distribution of the repetition origins that belong to the group into a two-dimensional distribution of a smaller number of new repetition origins. The layering unit 35c transforms the two-dimensional distribution of the origins into layers by taking the two-dimensional distribution of the repetition origins before the aggregation as a lower layer, taking a two-dimensional distribution of the new repetition origins after the aggregation as a higher layer, and associating the lower layer and the higher layer with each other. Here, the two-dimensional distribution of the repetition origins corresponding to the higher layer is defined independently of the two-dimensional distribution of the repetition origins corresponding to the lower layer.

Here, the clipping origins and the repetition origins may be simply referred to as “origins” when they are not particularly differentiated.

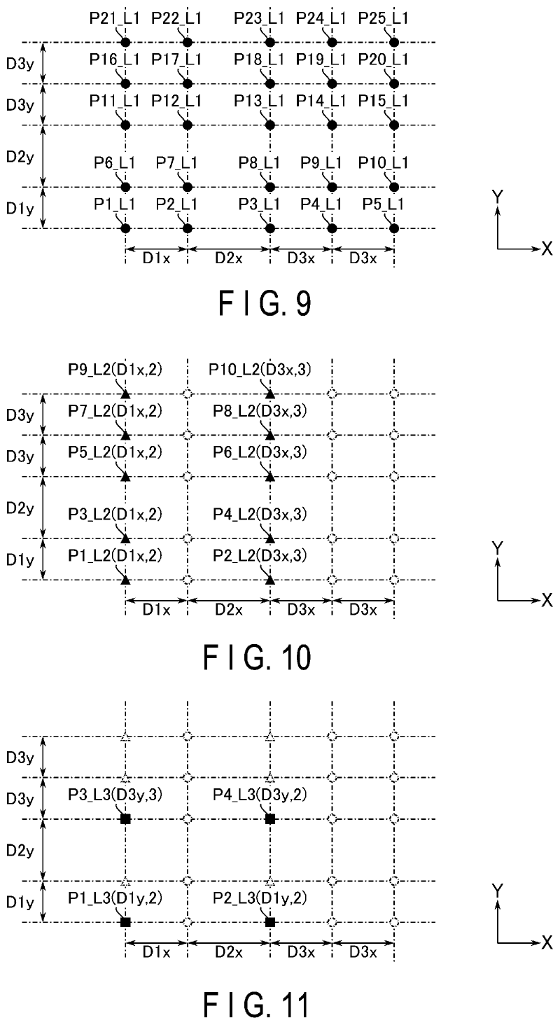

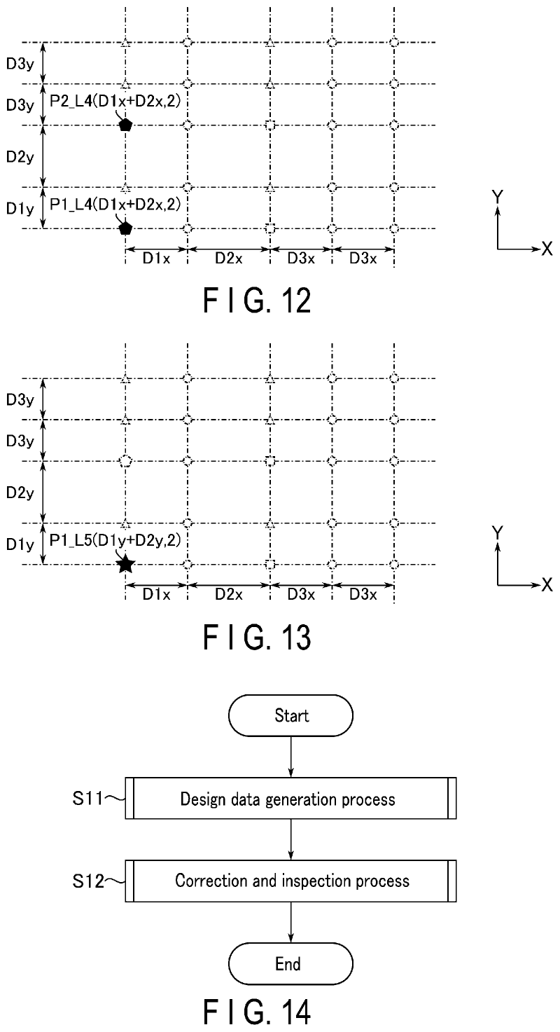

FIG. 9 is a diagram illustrating an example of periodicities possessed by a two-dimensional distribution of clipping origins in a first layer according to the embodiment. FIG. 10 is a diagram illustrating an example of periodicities possessed by a two-dimensional distribution of repetition origins in a second layer according to the embodiment. FIG. 11 is a diagram illustrating an example of periodicities possessed by a two-dimensional distribution of repetition origins in a third layer according to the embodiment. FIG. 12 is a diagram illustrating an example of periodicities possessed by a two-dimensional distribution of repetition origins in a fourth layer according to the embodiment. FIG. 13 is a diagram illustrating an example of periodicities possessed by a two-dimensional distribution of repetition origins in a fifth layer according to the embodiment. FIG. 9 to FIG. 13 illustrate how a two-dimensional distribution of clipping origins in a certain group obtained from flat data is transformed into layers in this order. In FIG. 9, clipping origins Pk in an i-th layer are indicated as “Pk_Li” (k and i are natural numbers). In FIG. 10 to FIG. 13, repetition origins Pk in an i-th layer are indicated as “Pk_Li(Dx, m)” in a case where the repetition origins Pk possess a periodicity (Dx, m). Note that the two-dimensional distributions of origins illustrated in FIG. 9 to FIG. 13 have no relation to the flat data items illustrated in FIG. 5 to FIG. 8.

In FIG. 9, a two-dimensional distribution of 25 clipping origins P1_L1 to P25_L1 in the first layer (i.e., a lowest layer) is indicated with black solid circles.

Five clipping origins P1_L1, P2_L1, P3_L1, P4_L1, and P5_L1 are arranged in this order at intervals D1x, D2x, D3x, and D3x in the X direction, respectively. Five clipping origins P6_L1, P7_L1, P8_L1, P9_L1, and P10_L1 are arranged in this order at the intervals D1x, D2x, D3x, and D3x in the X direction, respectively. Five clipping origins P11_L1, P12_L1, P13_L1, P14_L1, and P15_L1 are arranged in this order at the intervals D1x, D2x, D3x, and D3x in the X direction, respectively. Five clipping origins P16_L1, P17_L1, P18_L1, P19_L1, and P20_L1 are arranged in this order at the intervals D1x, D2x, D3x, and D3x in the X direction, respectively. Five clipping origins P21_L1, P22_L1, P23_L1, P24_L1, and P25_L1 are arranged in this order at the intervals D1x, D2x, D3x, and D3x in the X direction, respectively.

Five clipping origins P1_L1, P6_L1, P11_L1, P16_L1, and P21_L1 are arranged in this order at intervals D1y, D2y, D3y, and D3y in the Y direction, respectively. Five clipping origins P2_L1, P7_L1, P12_L1, P17_L1, and P22_L1 are arranged in this order at the intervals D1y, D2y, D3y, and D3y in the Y direction, respectively. Five clipping origins P3_L1, P8_L1, P13_L1, P18_L1, and P23_L1 are arranged in this order at the intervals D1y, D2y, D3y, and D3y in the Y direction, respectively. Five clipping origins P4_L1, P9_L1, P14_L1, P19_L1, and P24_L1 are arranged in this order at the intervals D1y, D2y, D3y, and D3y in the Y direction, respectively. Five clipping origins P5_L1, P10_L1, P15_L1, P20_L1, and P25_L1 are arranged in this order at the intervals D1y, D2y, D3y, and D3y in the Y direction, respectively.

From the two-dimensional distribution of the clipping origins P1_L1 to P25_L1 in the first layer illustrated in FIG. 9, the periodicity extraction unit 35a extracts a periodicity in the X direction. Specifically, the periodicity extraction unit 35a extracts a periodicity (D1x, 2) in the X direction from a set of the clipping origins P1_L1 and P2_L1, a set of the clipping origins P6_L1 and P7_L1, a set of the clipping origins P11_L1 and P12_L1, a set of the clipping origins P16_L1 and P17_L1, and a set of the clipping origins P21_L1 and P22_L1. In addition, the periodicity extraction unit 35a extracts a periodicity (D3x, 3) in the X direction from a set of the clipping origins P3_L1, P4_L1, and P5_L1, a set of the clipping origins P8_L1, P9_L1, and P10_L1, a set of the clipping origins P13_L1, P14_L1, and P15_L1, a set of the clipping origins P18_L1, P19_L1, and P20_L1, and a set of the clipping origins P23_L1, P24_L1, and P25_L1.

Based on the periodicity (D1x, 2) in the X direction, the aggregation unit 35b aggregates the set of the clipping origins P1_L1 and P2_L1, the set of the clipping origins P6_L1 and P7_L1, the set of the clipping origins P11_L1 and P12_L1, the set of the clipping origins P16_L1 and P17_L1, and the set of the clipping origins P21_L1 and P22_L1 into repetition origins P1_L2, P3_L2, P5_L2, P7_L2, and P9_L2, respectively. In addition, based on the periodicity (D3x, 3) in the X direction, the aggregation unit 35b aggregates the set of the clipping origins P3_L1, P4_L1, and P5_L1, the set of the clipping origins P8_L1, P9_L1, and P10_L1, the set of the clipping origins P13_L1, P14_L1, and P15_L1, the set of the clipping origins P18_L1, P19_L1, and P20_L1, and the set of the clipping origins P23_L1, P24_L1, and P25_L1 into repetition origins P2_L2, P4_L2, P6_L2, P8_L2, and P10_L2, respectively.

This enables the layering unit 35c to place, on the two-dimensional distribution in the first layer, a layer of a two-dimensional distribution of ten repetition origins P1_L2 to P10_L2 as illustrated in FIG. 10, as a two-dimensional distribution in the second layer. In FIG. 10, the ten repetition origins P1_L2 to P10_L2 in the second layer are indicated with black solid triangles.

Two repetition origins P1_L2 and P2_L2 are arranged in this order at an interval (D1x+D2x) in the X direction. Two repetition origins P3_L2 and P4_L2 are arranged in this order at the interval (D1x+D2x) in the X direction. Two repetition origins P5_L2 and P6_L2 are arranged in this order at the interval (D1x+D2x) in the X direction. Two repetition origins P7_L2 and P8_L2 are arranged in this order at the interval (D1x+D2x) in the X direction. Two repetition origins P9_L2 and P10_L2 are arranged in this order at the interval (D1x+D2x) in the X direction.

Five repetition origins P1_L2, P3_L2, P5_L2, P7_L2, and P9_L2 are arranged in this order at the intervals D1y, D2y, D3y, and D3y in the Y direction, respectively. Five repetition origins P2_L2, P4_L2, P6_L2, P8_L2, and P10_L2 are arranged in this order at the intervals D1y, D2y, D3y, and D3y in the Y direction, respectively.

From the two-dimensional distribution of the repetition origins P1_L2 to P10_L2 in the second layer illustrated in FIG. 10, the periodicity extraction unit 35a extracts a periodicity in the Y direction. Specifically, the periodicity extraction unit 35a extracts a periodicity (D1y, 2) in the Y direction from a set of repetition origins P1_L2 and P3_L2 and a set of repetition origins P2_L2 and P4_L2. In addition, the periodicity extraction unit 35a extracts a periodicity (D3y, 3) in the Y direction from a set of repetition origins P5_L2, P7_L2, and P9_L2 and a set of repetition origins P6_L2, P8_L2, and P10_L2.

Based on the periodicity (D1y, 2) in the Y direction, the aggregation unit 35b aggregates the set of the repetition origins P1_L2 and P3_L2 and the set of the repetition origins P2_L2 and P4_L2 into new repetition origins P1_L3 and P2_L3, respectively. In addition, based on the periodicity (D3y, 3) in the Y direction, the aggregation unit 35b aggregates the set of the repetition origins P5_L2, P7_L2, and P9_L2 and the set of the repetition origins P6_L2, P8_L2, and P10_L2 into new repetition origins P3_L3 and P4_L3, respectively.

This enables the layering unit 35c to place, on the two-dimensional distribution in the second layer, a layer of a two-dimensional distribution of four repetition origins P1_L3 to P4_L3 as illustrated in FIG. 11, as a two-dimensional distribution in the third layer. In FIG. 11, the four repetition origins P1_L3 to P4_L3 in the third layer are indicated with black solid squares.

Two repetition origins P1_L3 and P2_L3 are arranged in this order at the interval (D1x+D2x) in the X direction. Two repetition origins P3_L3 and P4_L3 are arranged in this order at the interval (D1x+D2x) in the X direction.

Two repetition origins P1_L3 and P3_L3 are arranged in this order at an interval (D1y+D2y) in the Y direction. Two repetition origins P2_L3 and P4_L3 are arranged in this order at the interval (D1y+D2y) in the Y direction.

From the two-dimensional distribution of the repetition origins P1_L3 to P4_L3 in the third layer illustrated in FIG. 11, the periodicity extraction unit 35a extracts a periodicity in the X direction. Specifically, the periodicity extraction unit 35a extracts a periodicity (D1x+D2x, 2) in the X direction from a set of repetition origins P1_L3 and P2_L3 and a set of repetition origins P3_L3 and P4_L3.

Based on the periodicity (D1x+D2x, 2) in the X direction, the aggregation unit 35b aggregates the set of the repetition origins P1_L3 and P2_L3 and the set of the repetition origins P3_L3 and P4_L3 into new repetition origins P1_L4 and P2_L4, respectively.

This enables the layering unit 35c to place, on the two-dimensional distribution in the third layer, a layer of a two-dimensional distribution of two repetition origins P1_L4 and P2_L4 as illustrated in FIG. 12, as a two-dimensional distribution in the fourth layer. In FIG. 12, the two repetition origins P1_L4 and P2_L4 in the fourth layer are indicated with black solid pentagons.

The two repetition origins P1_L4 and P2_L4 are arranged in this order at the interval (D1y+D2y) in the Y direction.

From the two-dimensional distribution of the repetition origins P1_L4 and P2_L4 in the fourth layer illustrated in FIG. 12, the periodicity extraction unit 35a extracts a periodicity in the Y direction. Specifically, the periodicity extraction unit 35a extracts a periodicity (D1y+D2y, 2) in the Y direction from a set of repetition origins P1_L4 and P2_L4.

Based on the periodicity (D1y+D2y, 2) in the Y direction, the aggregation unit 35b aggregates the set of the repetition origins P1_L4 and P2_L4 into a new repetition origin P1_L5.

This enables the layering unit 35c to place, on the two-dimensional distribution in the fourth layer, a layer of a two-dimensional distribution of one repetition origin P1_L5 as illustrated in FIG. 13, as a two-dimensional distribution in the fifth layer. In FIG. 13, the one repetition origin P1_L5 in the fifth layer is indicated with a black solid star.

### 1.2. Operation

### 1.2.1 Layout Data Generation Process

FIG. 14 is a flowchart illustrating an example of a layout data generation process in the layout generation device according to the embodiment.

Receiving a command to start generating layout data from a user (Start), the design module 21 executes a design data generation process (S11). The design module 21 thus generates design data. Details of the design data generation process will be described later.

The correction module 22 and the inspection module 23 execute a correction and inspection process on the design data generated in a process of S11 (S12). Details of the correction and inspection process will be described later.

As a process of S12 is ended, the layout data generation process is ended (End).

### 1.2.2 Design Data Generation Process

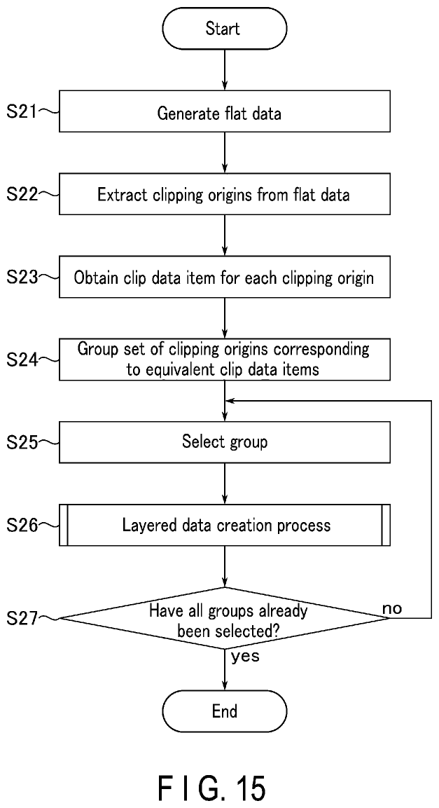

FIG. 15 is a flowchart illustrating an example of the design data generation process in the design module according to the embodiment. Processes of S21 to S27 illustrated in FIG. 15 correspond to details of the process of S11 illustrated in FIG. 14.

As the design data generation process is started (Start), the flat data creation unit 31 generates flat data (S21).

From the flat data generated in a process of S21, the origin extraction unit 32 extracts a plurality of clipping origins (S22).

The clip data obtainment unit 33 obtains a clip data item for each of the clipping origins extracted in a process of S22 (S23).

The grouping unit 34 groups the set of clipping origins that correspond to equivalent clip data items from among the clip data items obtained for the clipping origins in a process of S23 (S24).

The layered data creation unit 35 selects one of one or more groups classified in a process of S24 (S25).

The layered data creation unit 35 executes a layered data creation process on the group selected in a process of S25 (S26). This generates layered data in which a two-dimensional distribution of the clipping origins belonging to the group selected in the process of S25 is transformed into layers. Details of the layered data creation process will be described later.

After a process of S26, the layered data creation unit 35 determines whether all of the one or more groups have been selected (S27).

In a case where there is one or more unselected groups (S27; no), the layered data creation unit 35 selects one of the one or more unselected groups (S25). Then, subsequent processes of S26 and S27 are executed. In this manner, processes of S25 to S27 are repeated until all of the one or more groups are selected.

In a case where all of the one or more groups are already selected (S27; yes), the layered data creation unit 35 sends the set of layered data items of the groups as the design data to the correction module 22.

Thus, the design data generation process is ended (End).

### 1.2.3 Layered Data Creation Process

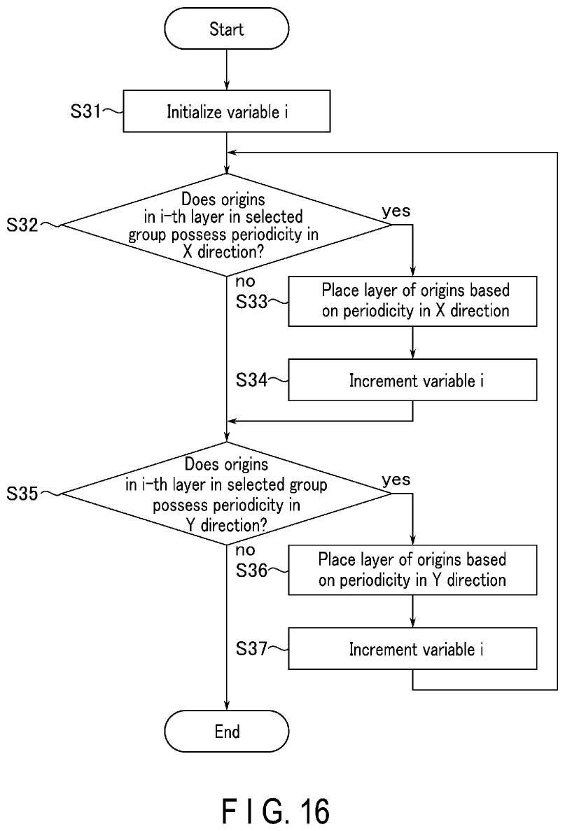

FIG. 16 is a flowchart illustrating an example of the layered data creation process in the layered data creation unit according to the embodiment. Processes of S31 to S37 illustrated in FIG. 16 correspond to details of the process of S26 illustrated in FIG. 15.

As the layered data creation process is started (Start), the layered data creation unit 35 initializes a variable i to, for example, “1” (S31).

The periodicity extraction unit 35a determines whether a two-dimensional distribution of origins in an i-th layer in the group selected in the process of S25 possesses a periodicity in the X direction (S32).

In a case where the two-dimensional distribution of the origins in an i-th layer possesses a periodicity in the X direction (S32; yes), the aggregation unit 35b aggregates the two-dimensional distribution of the origins based on the periodicity in the X direction determined to be possessed in a process of S32. The layering unit 35c then places, on the two-dimensional distribution of the origins in the i-th layer, a layer of the aggregated two-dimensional distribution as a two-dimensional distribution of origins in an (i+1)-th layer (S33).

After a process of S33, the layered data creation unit 35 increments the variable i (S34).

In a case where the two-dimensional distribution of the origins in the i-th layer possesses no periodicity in the X direction (S32; no) or after a process of S34, the periodicity extraction unit 35a determines whether the two-dimensional distribution of the origins in the i-th layer in the group selected in the process of S25 possesses a periodicity in the Y direction (S35).

In a case where the two-dimensional distribution of the origins in the i-th layer possesses a periodicity in the Y direction (S35; yes), the aggregation unit 35b aggregates the two-dimensional distribution of the origins based on the periodicity in the Y direction determined to be possessed in a process of S35. The layering unit 35c then places, on the two-dimensional distribution of the origins in the i-th layer, a layer of the aggregated two-dimensional distribution as a two-dimensional distribution of origins in an (i+1)-th layer (S36).

After a process of S36, the layered data creation unit 35 increments the variable i (S37).

After a process of S37, the periodicity extraction unit 35a determines whether the two-dimensional distribution of origins in an i-th layer in the group selected in the process of S25 possesses a periodicity in the X direction (S32). Then, subsequent processes of S33 to S37 are executed. In this manner, processes of S32 to S37 are repeated until the two-dimensional distribution of origins in a highest layer belonging to the group selected in the process of S25 possesses neither a periodicity in the X direction nor a periodicity in the Y direction.

In a case where the two-dimensional distribution of the origins in the i-th layer possesses no periodicity in the Y direction (S35; no), the layered data creation process is ended (End).

### 1.2.4 Correction And Inspection Process

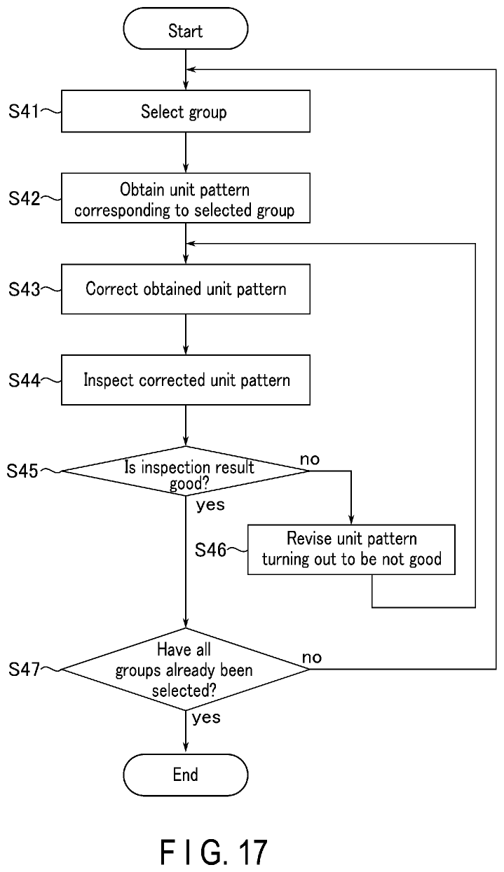

FIG. 17 is a flowchart illustrating an example of the correction and inspection process in the correction module and the inspection module according to the embodiment. Processes of S41 to S47 illustrated in FIG. 17 correspond to details of the process of S12 illustrated in FIG. 14.

As the correction and inspection process is started (Start), the correction module 22 selects one of the one or more groups classified in the process of S24 (S41).

The correction module 22 obtains a unit pattern corresponding to the group selected in a process of S41 (S42).

The correction module 22 executes a correction process on the unit pattern obtained in a process of S42 (S43). Specifically, the correction module 22 executes the OPC process and/or the SRAF generation process on the unit pattern obtained in the process of S42. The OPC process and/or the SRAF generation process may be model-based process or rule-based process.

The inspection module 23 executes an inspection process on the unit pattern corrected in a process of S43 (S44). Specifically, the inspection module 23 executes a lithography simulation on the unit pattern corrected in the process of S43.

The inspection module 23 determines whether the result of the inspection process in S44 is good (S45).

In a case where the result is not good (S45; no), the inspection module 23 revises the unit pattern that has turned out to be not good (S46).

The correction module 22 executes the correction process on the unit pattern revised in a process of S46 (S43). In this manner, processes of S43 to S46 are repeated until the result of the inspection process turns out to be good.

In a case where the result is good (S45; yes), the correction module 22 determines whether all of the one or more groups have been selected (S47).

In a case where there is any unselected group (S47; no), the correction module 22 selects the unselected group (S41). In this manner, the processes of S41 to S47 are repeated until all of the one or more groups are selected. Note that whether the rule-based process or the model-based process is to be applied to the OPC process and/or the SRAF generation process in S43 may be switched for each selected group.

In a case where all of the one or more groups are already selected (S47; yes), the correction and inspection process is ended (End).

### 1.3 Effect According to Embodiment

According to the embodiment, the periodicity extraction unit 35a extracts periodicities from a first distribution being the highest layer of a two-dimensional distribution of origins classified into an identical group (in a case where the two-dimensional distribution is not transformed into layers, the periodicity extraction unit 35a extracts periodicities from a two-dimensional distribution of clipping origins classified into an identical group). Based on the periodicities extracted from the periodicity extraction unit 35a, the aggregation unit 35b aggregates the first distribution into a second distribution of a smaller number of new repetition origins. The layering unit 35c places a layer of the second distribution after the aggregation as a higher layer of the first distribution before the aggregation. The layered data creation unit 35 repeats a combination of the above processes by the periodicity extraction unit 35a, the aggregation unit 35b, and the layering unit 35c. The repetition multiplexes the two-dimensional distribution of the origins classified into the identical group into a layered structure based on the periodicities. Therefore, a data size of the layered data can be reduced to a data size on an order of several MBs with respect to a data size of the flat data, which is on an order of several GBs. Accordingly, it is possible to reduce a processing load of expansion of a result of the subsequent correction and inspection process to the entire layout data.

In addition, the layered data creation unit 35 alternates a repetition unit for a periodicity in the X direction and a repetition unit for a periodicity in the Y direction. This enables periodicities in given directions in a two-dimensional distribution to be taken into account.

Furthermore, the periodicities are defined based on the parameters including number of origins arranged at equal intervals in predetermined directions and the intervals. This enables the aggregation unit 35b to aggregate any number of origins arranged in equal intervals into one origin.

### 2. Modifications

The above-described embodiment can be subjected to various modifications.

In the above-described embodiment, a case where a size of the unit pattern is equal to that of one clip data item is described. However, this is not limiting. For example, the unit pattern may be a plurality of clip data items integrated. Below, a description will mainly be given below of a configuration and an operation different from those of the embodiment. The description of the same configurations and operations as in the embodiment will be omitted as appropriate.

### 2.1 Design Module

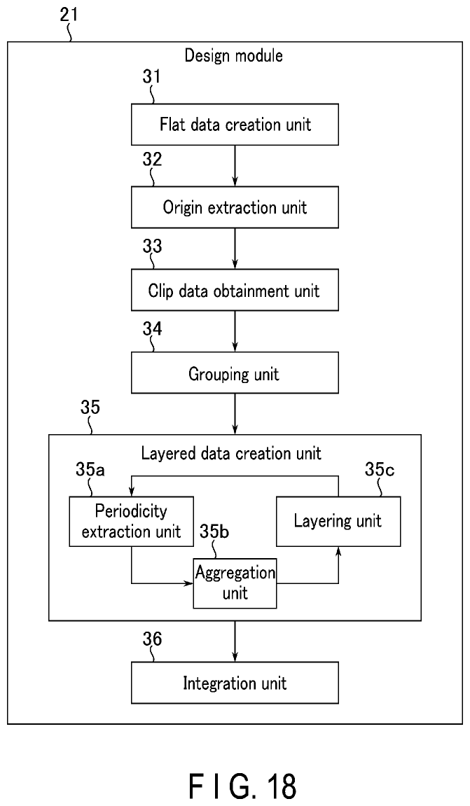

FIG. 18 is a block diagram illustrating an example of a functional configuration of a design module according to a modification. FIG. 18 corresponds to FIG. 4 in the embodiment. A design module 21 illustrated in FIG. 18 includes a flat data creation unit 31, an origin extraction unit 32, a clip data obtainment unit 33, a grouping unit 34, a layered data creation unit 35, and an integration unit 36.

Configurations of the flat data creation unit 31, the origin extraction unit 32, the clip data obtainment unit 33, the grouping unit 34, and the layered data creation unit 35 according to the modification are the same as the configurations of the flat data creation unit 31, the origin extraction unit 32, the clip data obtainment unit 33, the grouping unit 34, and the layered data creation unit 35 according to the embodiment, and therefore descriptions thereof will be omitted.

The integration unit 36 integrates a plurality of groups into one group based on layered structures of layered data items. Specifically, the integration unit 36 compares the layered structures of the layered data items across the groups and integrates a plurality of groups having an identical layered structure into one group. When integrating the groups, the integration unit 36 synthesizes one unit pattern by superimposing a plurality of unit patterns corresponding to the groups to be integrated.

With the above-described configuration, it is possible to compile a plurality of unit patterns each having a repetitive pattern of the same periodicity into one unit pattern that is larger in size than clip data.

### 2.2 Design Data Generation Process

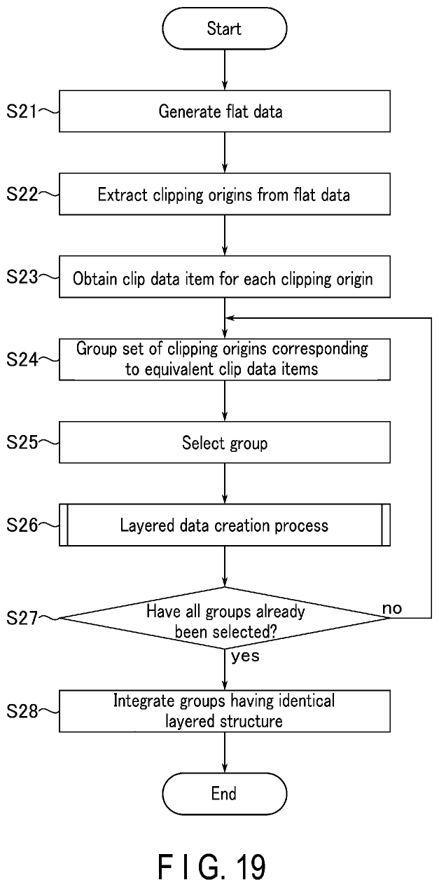

FIG. 19 is a flowchart illustrating an example of the design data generation process in the design module according to the modification. FIG. 19 corresponds to FIG. 15 in the embodiment.

Processes of S21 to S27 in FIG. 19 are the same as the processes of S21 to S27 in FIG. 15, and thus the descriptions thereof will be omitted.

In a case where all of the one or more groups are already selected (S27; yes), the integration unit 36 integrates, from among the groups, a plurality of groups having an identical layered structure into one group (S28). The unit pattern corresponding to the integrated group is a pattern into which a plurality of clip data items corresponding to the groups to be integrated are superimposed.

As a process of S28 is ended, the design data generation process is ended (End).

### 2.3 Effect According to Modification

According to the modification, the integration unit 36 integrates the groups having the identical layered structure into one group. The unit pattern of the integrated group is a pattern into which the unit patterns of the groups to be integrated are superimposed. This enables the correction and inspection process to be executed simultaneously on the groups having the identical layered structure. Therefore, it is possible to further reduce a load of the correction and inspection process. In addition, it is possible to grasp the largest pattern of repetitive patterns that are most basic among layout patterns.

### 3. Other Respects

The above-described embodiment and modification can be subjected to various modifications.

In the above-described embodiment and modification, a case where, in the layered data creation process, the layering process based on a periodicity in the X direction and the layering process based on a periodicity in the Y direction correspond to different layers in a layered structure is described. However, this is not limiting. For example, a combination of the layering process based on a periodicity in the X direction and the layering process based on a periodicity in the Y direction may be associated with the identical layered structure. That is, in a case where two layers adjacent to each other are a layer formed by the layering process based on a periodicity in the X direction and a layer formed by the layering process based on a periodicity in the Y direction, these two layers may be aggregated into one layer.

In the above-described embodiment and modification, a case where the program for executing the design data generation process, the layered data creation process, and the layout data generation process is executed by the layout generation device 2 is described. However, this is not limiting. For example, the program for executing the design data generation process, the layered data creation process, and the layout data generation process may be executed on cloud computational resources.

While certain embodiments have been described, these embodiments have been presented by way of example only, and are not intended to limit the scope of the invention. Indeed, the embodiments described herein may be embodied in a variety of other forms; furthermore, various omissions, substitutions and changes in the form of the embodiments described herein may be made without departing from the spirit of the inventions. The embodiments and modifications are included in the scope and spirit of the invention and are included in the scope of the claimed inventions and their equivalents.

What is claimed is:

1. A layout generation device comprising:
an extraction unit extracting a plurality of origins from design data for a photomask;
an obtainment unit obtaining a region corresponding to each of the origins;
a grouping unit classifying the origins into one or more groups; and
a layering unit transforming a distribution of origins corresponding to each of the one or more groups into layers,
wherein one or more sets of origins that form an equivalent pattern within regions corresponding to the origins are classified into an identical group, and
the layering unit is configured to repeat:
extracting a periodicity from a first distribution corresponding a first layer being the highest layer of the distribution;
aggregating the first distribution into a second distribution based on the periodicity; and
placing a second layer of the second distribution as a higher layer than the first layer of the first distribution.

2. The layout generation device according to claim 1, wherein
a center of the region is a position of an origin corresponding to the region, and
an edge of the region is located at a distance equal to or greater than an optical radius from the center.

3. The layout generation device according to claim 1, further comprising a correction module executing an assist feature generation process on a pattern corresponding to each of the one or more groups.

4. The layout generation device according to claim 3, wherein the correction module is configured to select, independently of each of the one or more groups, whether a rule-based process or a model-based process is to be applied to the assist feature generation process.

5. The layout generation device according to claim 1, further comprising a correction module executing an optical proximity correction process on a pattern corresponding to each of the one or more groups.

6. The layout generation device according to claim 5, wherein the correction module is configured to select, independently of each of the one or more groups, whether a rule-based process or a model-based process is to be applied to the optical proximity correction process.

7. The layout generation device according to claim 5, wherein a position of the origin corresponding to the region corresponds to a central processing point of the optical proximity correction process on the pattern.

8. The layout generation device according to claim 1, further comprising
an inspection module executing a lithography simulation process on a pattern corresponding to each of the one or more groups.

9. The layout generation device according to claim 8, wherein a position of the origin corresponding to the region corresponds to a central processing point of the lithography simulation process on the pattern.

10. The layout generation device according to claim 1, further comprising
an integration unit integrating a first group and a second group that have an identical layered structure.

11. The layout generation device according to claim 1, wherein
the distribution is a two-dimensional distribution extending in a first direction and a second direction that intersect with each other, and
the layering unit is configured to alternate a repetition unit for the first direction and a repetition unit for the second direction.

12. The layout generation device according to claim 1, wherein the periodicity is defined based on a parameter including the number of origins arranged at an equal interval in a predetermined direction and the interval.

13. The layout generation device according to claim 1, wherein, from among the origins, one or more sets of origins that form an identical pattern, patterns in line symmetry, or patterns in rotational symmetry within regions corresponding to the origins are classified into an identical group.

14. A layout generating method comprising:
extracting a plurality of origins from design data for a photomask;
obtaining a region corresponding to each of the origins;
classifying the origins into one or more groups; and
transforming a distribution of origins corresponding to each of the one or more groups into layers,
wherein one or more sets of origins that form an equivalent pattern within regions corresponding to the origins are classified into an identical group, and
the transforming includes repeating:
extracting a periodicity from a first distribution corresponding to a first layer being the highest layer of the distribution;
aggregating the first distribution into a second distribution based on the periodicity; and
placing a second layer of the second distribution as a higher layer than the first layer of the first distribution.

15. A storage medium that stores a program for causing a computer to execute:
extracting a plurality of origins from design data for a photomask;
obtaining a region corresponding to each of the origins;
classifying the origins into one or more groups; and
transforming a distribution of origins corresponding to each of the one or more groups into layers,
wherein one or more sets of origins that form an equivalent pattern within regions corresponding to the origins are classified into an identical group, and
the transforming includes repeating:
extracting a periodicity from a first distribution corresponding to a first layer being the highest layer of the distribution;
aggregating the first distribution into a second distribution based on the periodicity; and
placing a second layer of the second distribution as a higher layer than the first layer of the first distribution.
